(19) United States
(12) Patent Application Publication
(10) Pub. No.: US 2010/0241928 A1
(43) Pub. Date: Sep. 23, 2010

(54) Data Processing System Having ECC Encoding and Decoding Circuits Therein with Code Rate Selection Based on Bit Error Rate Detection

(76) Inventors: Jaehong Kim, Seoul (KR); Yong June Kim, Seoul (KR); Junjin Kong, Yongin-si (KR); Seung-Hwan Song, Suwon-si (KR)

Correspondence Address: MYERS BIGEL SIBLEY & SAJOVEC, PO BOX 37428, RALEIGH, NC, 27627, US

(21) Appl. No.: 12/716,793

(22) Filed: Mar. 3, 2010

(30) Foreign Application Priority Data
Mar. 18, 2009 (KR) 2009-0023167

(51) Int. Cl. H03M 13/05; G06F 11/10

(52) U.S. Cl. 714/763; 714/E11.032

(57) ABSTRACT

A data processing system includes an error checking and correction (ECC) encoding circuit, an integrated circuit memory and a code rate control circuit. The ECC encoding circuit is configured to selectively apply a plurality of unique ECC code rates to write data received by the data processing system during an operation to convert the write data into encoded data, in response to a code rate selection signal. The integrated circuit memory includes a plurality of storage regions therein. These storage regions are configured to receive respective portions of the encoded data from the ECC encoding circuit. The code rate control circuit is configured to generate the code rate selection signal. This code rate selection signal has a value that specifies the corresponding ECC code rate to be applied to respective portions of the write data.

### REFERENCE TO PRIORITY APPLICATION

This application claims priority to Korean Patent Application No. 10-2009-0023167, filed Mar. 18, 2009, the contents of which are hereby incorporated herein by reference.

### FIELD OF THE INVENTION

The present invention relates to data processing systems and, more particularly, to data processing systems having ECC encoding and decoding circuits therein.

### BACKGROUND

When digital information is transferred, recorded, or reproduced, in some examples, errors can occur in portions of the digital information due to various causes. There are known technologies which employ error detecting code or error correction code to detect such errors and correct any detected errors. There is no fundamental difference between an error detecting code and an error correction code, which are referred to collectively as error control codes. Similarly, error detection and error correction may be referred to collectively as error control.

In transferring or recoding digital information using error control codes, for example, m-bit error control information (redundant bits) is appended to k-bit digital information (information bits), so that (k+m)-bit codeword is generated. The codeword thus generated may be transferred into a channel. At a transfer destination of the codeword, error detection and/or error correction may be made using redundant bits included in the codeword. A process of generating a codeword is called ‘encoding’, and error detection and/or error correction based on the codeword may be called ‘decoding’. The encoding of digital information may be a process of generating redundant bits (hereinafter, referred to as ECC parity data) with the view to detect/correct errors included in digital information based on the digital information and adding/attaching the ECC parity data to the digital information. In general, data (digital information) before encoding is called a message. Data after encoding (digital information having added ECC parity data) is generally called a codeword.

With a view to improve the reliability during transferring or recoding of digital information, it may be preferable to use error control codes having the high error correction/error detection capability (for example, error control codes having the low code rates). But, in the event that codes having the high error correction/error detection capability are used, a bit length of redundant bits tends to become longer, and the information transmission efficiency tends to become bad. Further, since the constant code rate is used regardless of the characteristic of a channel by which data is transferred, it may be difficult to optimize the overhead of error control encoding.

### SUMMARY

A data processing system according to embodiments of the inventive concept includes an error checking and correction (ECC) encoding circuit, an integrated circuit memory and a code rate control circuit. The ECC encoding circuit is configured to selectively apply a plurality of unique ECC code rates to write data received by the data processing system during an operation to convert the write data into encoded data, in response to a code rate selection signal. The integrated circuit memory includes a plurality of storage regions therein. These storage regions are configured to receive respective portions of the encoded data from the ECC encoding circuit. The code rate control circuit is configured to generate the code rate selection signal. This code rate selection signal has a value that specifies the corresponding ECC code rate to be applied to respective portions of the write data. In particular, the code rate control circuit may be configured to set the value of the code rate selection signal so that each of the plurality of storage regions within the integrated circuit memory receive write data encoded with a unique ECC code rate.

In some additional embodiments of the inventive concept, an ECC decoding circuit may be provided, which is configured to decode first data read from a first storage region within the integrated circuit memory and determine a first bit error rate associated with the first data. Moreover, the ECC encoding circuit is further configured to reduce a code rate associated with write data being written to the first storage region in the event the first bit error rate determined by the ECC decoding circuit exceeds a first threshold.

According to still further embodiments of the inventive concept, a data processing system is provided, which includes an integrated circuit memory, an error checking and correction (ECC) encoding circuit, an ECC decoding circuit and a code rate control circuit. The integrated circuit memory is configured to have a plurality of storage regions therein. The error checking and correction (ECC) encoding circuit, which is responsive to a code rate selection signal, is configured to encode first data at a first code rate determined by the code rate selection signal during an operation to write the first data into a first storage region within the integrated circuit memory. The ECC decoding circuit is configured to decode the first data read from the first storage region. The ECC decoding circuit may also be configured to determine a first bit error rate associated with the first data. The code rate control circuit is configured to change a value of the code rate selection signal in the event the first bit error rate determined by the ECC decoding circuit exceeds a first threshold. The code rate control circuit may be further configured to set the value of the code rate selection signal so that each of the plurality of storage regions within the integrated circuit memory receive write data encoded with a unique code rate.

### BRIEF DESCRIPTION OF THE FIGURES

FIG. 1 is a block diagram showing a data processing system according to an embodiment of the inventive concept.

FIG. 2 is a block diagram showing an ECC encoding and decoding block and a code rate controlling block illustrated in FIG. 1.

FIGS. 3A and 3B are block diagrams showing an ECC encoding and decoding block according to embodiments of the inventive concept.

FIGS. 4A to 4C are diagrams showing code rate changing manners.

FIG. 5 is a flowchart showing a write operation of a data processing system according to an embodiment of the inventive concept.

FIG. 6 is a diagram showing code rates stored in a code rate storing part illustrated in FIG. 2.

FIG. 7 is a flowchart showing a read operation of a data processing system according to an embodiment of the inventive concept.

FIG. 8 is a flowchart showing an erase operation of a data processing system according to an embodiment of the inventive concept.

FIG. 9 is a block diagram showing a computing system including a memory and a controller illustrated in FIG. 1.

### DETAILED DESCRIPTION OF THE EMBODIMENTS

The inventive concept is described more fully hereinafter with reference to the accompanying drawings, in which embodiments of the inventive concept are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. Like numbers refer to like elements throughout.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

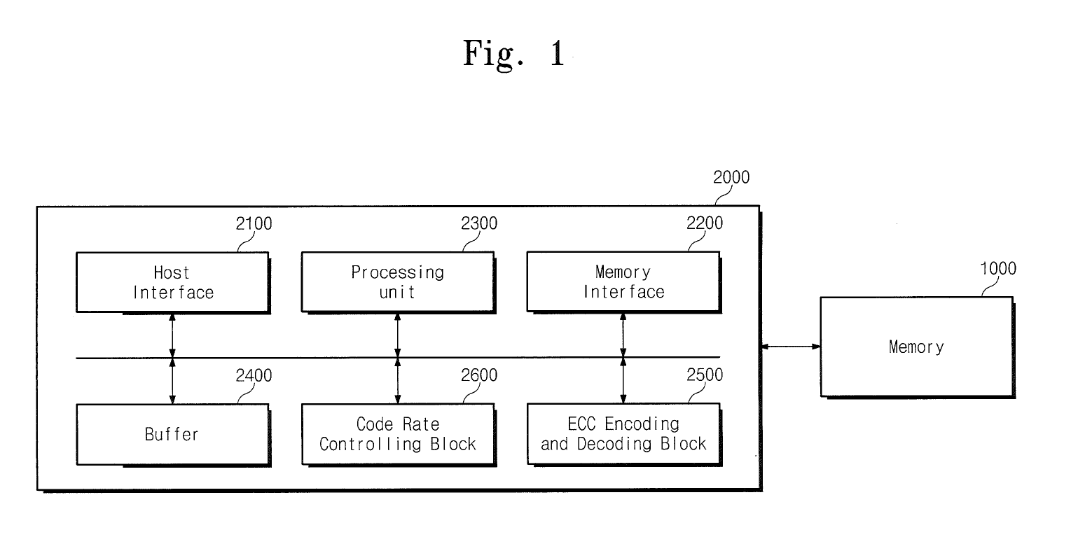

FIG. 1 is a block diagram showing a data processing system according to an embodiment of the inventive concept.

Referring to FIG. 1, a data processing system according to an embodiment of the inventive concept may include a memory 1000 as a storage media and a controller 2000 configured to control the memory 1000. The memory 1000 may include a flash memory, DRAM, PRAM, FRAM, MRAM, and the like. The memory 1000 may be used as a channel which receives data from the controller 2000 and outputs the received data to the controller 2000. The memory 1000, although not shown in FIG. 1, may include storage elements, each of which is configured to store single-bit data or multi-bit/multi-level data. The storage elements of the memory 1000 may be arranged to have a two-dimensional array structure or a three-dimensional array structure.

The memory 1000 is not limited to a semiconductor memory. For example, the memory 1000 may include an optical disk, a magnetic disk, and the like. A channel using the memory 1000 may be formed of a wireless channel, a wire channel, and the like.

The controller 2000 may be configured to store data in the memory 1000 in response to a write/program request from an external device (for example, host) and to read data from the memory 1000 in response to a read request from the external device. The controller 2000 may include a host interface 2100, a memory interface 2200, a processing unit 2300, a buffer memory 2400, an ECC encoding and decoding block 2500, and a code rate controlling block 2600.

The host interface 2100 may be connected/coupled with an external device by a NOR interface or standardized interfaces such as ATA, SATA, PATA, USB, SCSI, ESDI, and IDE interfaces. The memory interface 2200 may be configured to interface with the memory 1000. Herein, it is well comprehended that the host interface 2100 and the memory interface 2200 are changed variously according to the memory 1000 functioning as a channel and according to a host. The processing unit 2300 may be configured to an overall operation of the controller 2300. The ECC encoding and decoding block 2500 may be configured to encode data being stored in the memory 1000 and to decode data read out from the memory 1000.

A code rate of the ECC encoding and decoding block 2500 may be changed by the code rate controlling block 2600 according to a characteristic of the data processing system and/or a status of the memory 1000 (or, a status of a channel formed of the memory 1000). Changing of the code rate, for example, may be made according to wear-leveling information such as a program/erase cycle, a bit error rate (BER), a used time, an error frequency after reading by decoding of an error control code at a read request, and the like. Herein, the code rate may be determined by a bit length C of a codeword encoded by the ECC encoding and decoding block 2500 and a bit length M of a message included in the codeword. That is, the code rate (R) may be determined by M/C.

The code rate controlling block 2600, as will be described below, may be configured to store code rates each corresponding to storage areas of the memory 1000, for example, to areas each corresponding to a memory block, a page, a sector, or a chip. The code rates may be updated by the code rate controlling block 2600 according to a bit error rate and wear-leveling information. When a program operation for the memory 1000 is request from the external device, the code rate controlling block 2600 may select a code rate of a storage area being accessed and set the ECC encoding and decoding block 2500 with the selected code rate. The ECC encoding and decoding block 2500 may encode data according to the selected/set code rate. When a read operation for the memory 1000 is request from the external device, the code rate controlling block 2600 may select a code rate of a storage area being accessed and set the ECC encoding and decoding block 2500 with the selected code rate. The ECC encoding and decoding block 2500 may decode data according to the selected/set code rate.

As described above, it is possible to optimize the overhead of the error control encoding by changing a code rate of the ECC encoding and decoding block 2500 according to a memory state (or, a state of the data processing system). Further, it is possible to better the reliability of the data processing system by the optimized error control encoding.

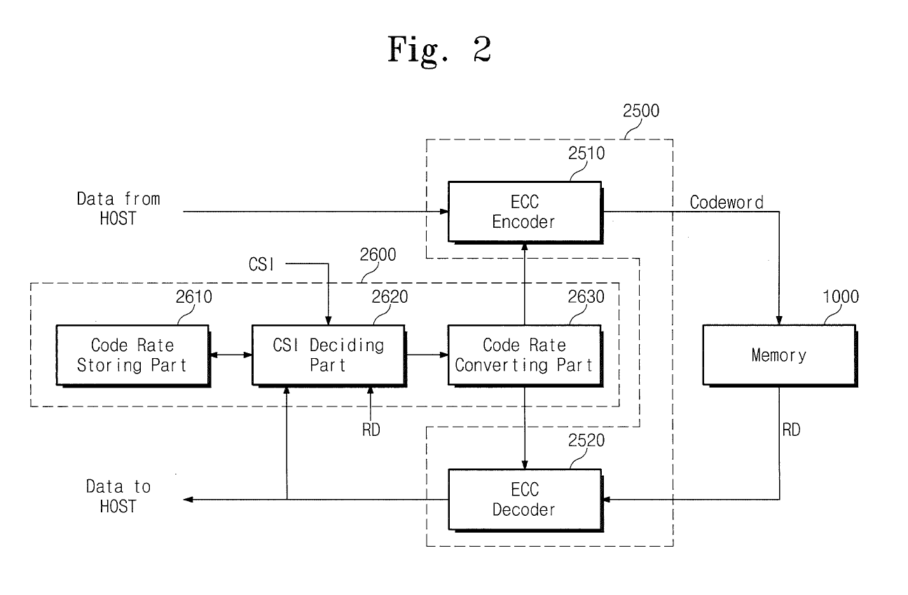

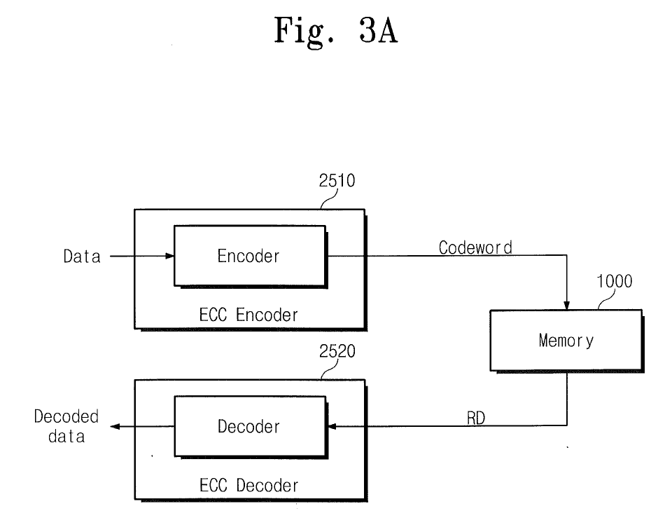

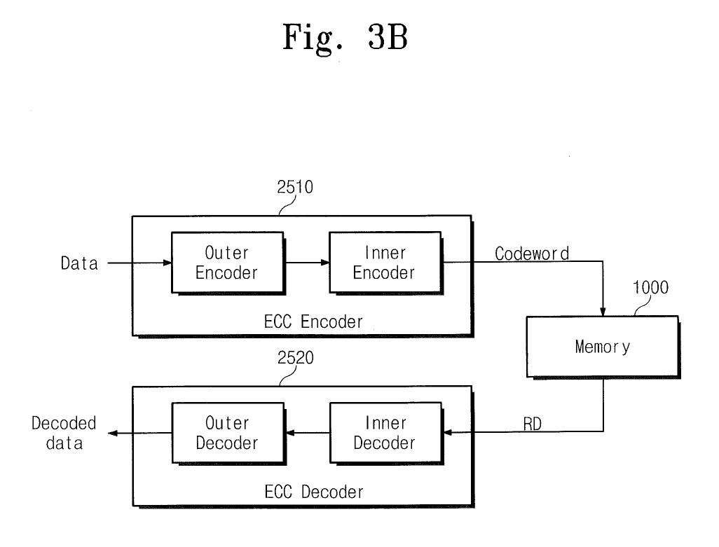

FIG. 2 is a block diagram showing an ECC encoding and decoding block and a code rate controlling block illustrated in FIG. 1, and FIGS. 3A and 3B are block diagrams showing an ECC encoding and decoding block according to embodiments of the inventive concept.

Firstly referring to FIG. 2, an ECC encoding and decoding block 2500 may include an ECC encoder 2510 and an ECC decoder 2520. The ECC encoder 2510 may encode data from a host to generate a codeword. The codeword may be sent to a memory 1000. A code rate of the ECC encoder 2510 may be set by a code rate controlling block 2600. The ECC decoder 2520 may decode data read out from the memory 1000 and send the decoded data to the host. A code rate of the ECC decoder 2520 may be set by the code rate controlling block 2600.

In an exemplary embodiment, the ECC encoder 2510 may be configured to encode data using one code or using two different codes. In case of encoding data using one code, as illustrated in FIG. 3A, the ECC encoder 2510 may be formed of an encoder. Likewise, in case of decoding using one code, as illustrated in FIG. 3A, the ECC decoder 2520 may be formed of a decoder. On the other hand, it is possible to use a manner of encoding data using two different codes (referred as to a concatenated coding manner). In case of the concatenated coding manner, as illustrated in FIG. 3B, the ECC encoder 2510 may be formed of an outer encoder generating an outer codeword using an outer code and an inner encoder generating an inner codeword using an inner code. In this case, a code rate of the outer encoder and a code rate of the inner encoder may be set individually by the code rate controlling block 2600. Alternatively, a code rate of the outer encoder and a code rate of the inner encoder may be set identically or differently by the code rate controlling block 2600. If the ECC encoder 2510 uses the concatenated coding manner, as illustrated in FIG. 3B, the ECC decoder 2520 may be formed of an outer decoder and an inner decoder. Like the ECC encoder 2510, a code rate of the outer decoder and a code rate of the inner decoder may be set individually by the code rate controlling block 2600. Alternatively, a code rate of the outer decoder and a code rate of the inner decoder may be set identically or differently by the code rate controlling block 2600.

Returning to FIG. 2, the code rate controlling block 2600 may include a code rate storing part 2610, a channel status information (CSI) deciding part 2620, and a code rate converting part 2630. The code rate storing part 2610 may be used to store code rates each corresponding to storage areas of a memory 1000, for example, such as memory blocks, pages, sectors, chips, layers (3D array structure), and the like. The code rate storing part 2610 may be formed of a volatile or non-volatile memory. In the event that the code rate storing part 2610 is formed of a volatile memory, code rates of the code rate storing part 2610, for example, may be stored in the memory 1000. The code rates stored in the memory 1000 may be loaded onto the code rate storing part 2610 at power-up. The code rate storing part 2610 may be formed of a part of a buffer memory 2400 in FIG. 1 or a separate memory.

The CSI deciding part 2620 may be configured to manage code rates of storage areas stored in the code rate storing part 2610 based on the CSI and BER. Management of the code rates may be made as follows.

Basically, code rates stored in the code rate storing part 2610 may be set to the largest code rate as a default value, respectively. Afterwards, the code rates stored in the code rate storing part 2610 may be varied according to CSI, BER, a used time of a storage area, an error frequency after reading by decoding of the error control code at a read request, and the like. The channel status information CSI may be loaded onto the buffer memory 2400 from the memory 1000 at power-up. The loaded CSI onto the buffer memory 2400 may be managed by a processing unit 2300, and the CSI deciding part 2620 refers to the CSI to manage code rates of storage areas.

When a program operation for the memory 1000 is requested, the CSI deciding part 2620 may read a code rate, corresponding to address information of a storage area being accessed, from the code rate storing part 2610 and transfer the read code rate into the code rate converting part 2630. The code rate thus decided may be set to the ECC encoding and decoding block 2500 through the code rate converting part 2630. The ECC encoding and decoding block 2500 may encode incoming data according to the set code rate, and the encoded data, that is, a codeword may be stored in the memory 1000.

When a read operation for the memory 1000 is requested, the CSI deciding part 2620 may read a code rate, corresponding to address information of a storage area being accessed, from the code rate storing part 2610 and transfer the read code rate into the code rate converting part 2630. The code rate thus decided may be set to the ECC encoding and decoding block 2500 through the code rate converting part 2630. The ECC encoding and decoding block 2500 may decode read data RD according to the set code rate, and the decoded data may be sent to an external device. At the same time, the CSI deciding part 2620 may decide a bit error rate (BER) based on the read data RD and the decoded data. The CSI deciding part 2620 may judge whether the decided BER is over a reference value. The CSI deciding part 2620 may change a code rate of the accessed storage area according to the judgment result. When the decided BER is judged to be over a reference value, or, if the code rate of the accessed storage area is changed, the CSI deciding part 2620 may request a re-program operation for the accessed storage area from the processing unit 2300. With the re-program operation, data stored in the accessed storage area may be re-programmed in the same storage area or moved into another storage area based on the changed code rate.

Exemplary re-program operations are described in U.S. Pat. No. 7,079,422 entitled “PERIODIC REFRESH OPERATIONS FOR NON-VOLATILE MULTIPLE-BIT-PER-CELL MEMORY”, KR Patent No. 0764748 entitled “FLASH MEMORY DEVICE WITH IMPROVED REFRESH FUNCTION”, U.S. Publication No. 2008-0068912 entitled “FLASH MEMORY DEVICE AND REFRESH METHOD THEREOF”, and U.S. Publication No. 2008-0055997 entitled “FLASH MEMORY DEVICE AND REFRESH METHOD”, the entirety of which is incorporated herein by reference.

In the event that an erase operation is requested with respect to the memory 1000, the CSI deciding part 2620 may judge whether channel status information CSI of a storage area being accessed/erased exceeds a reference value. If the channel status information CSI (for example, a program/erase cycle, a used time, etc.) of a storage area being accessed/erased exceeds a reference value, the CSI deciding part 2620 may change a code rate corresponding to a storage area being erased. Afterwards, the requested erase operation may be carried out. Encoding and decoding at a read/program operation of a storage area being erased may be made according to the changed code rate.

In an exemplary embodiment, it is possible to use one or more reference values to judge the CSI. The CSI may include a used time of a memory/data processing system, a used time of each storage area of the memory 1000, an access number of each storage area of the memory 1000 such as long-term data or short-term data, an error frequency after reading by decoding of an error control code at a read request, and the like

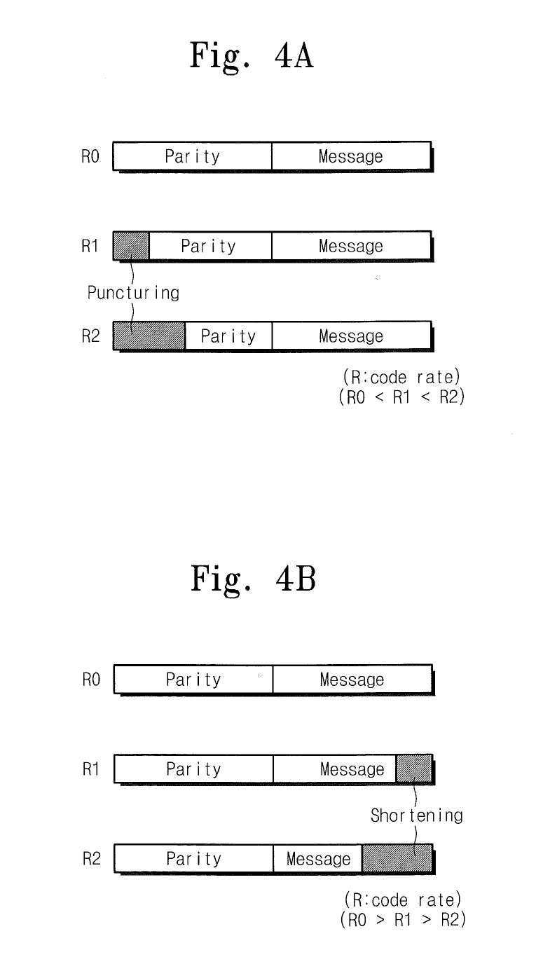

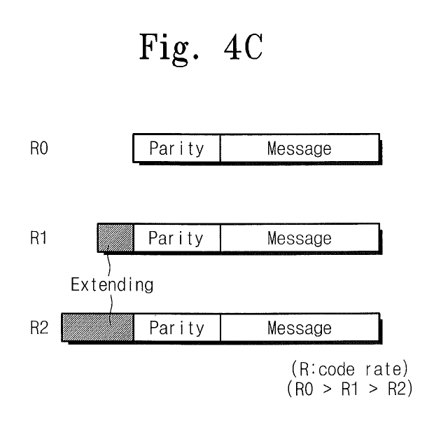

FIGS. 4A to 4C are diagrams showing code rate changing manners.

Change of code rates may be made by various techniques. For example, code rates may be changed by puncturing, shorting, and extending.

With the puncturing, as illustrated in FIG. 4A, a part of parity bits may be removed after encoded by an error correction code. A code rate R may increase gradually by removing parity bits partially. In the case of the shorting, as illustrated in FIG. 4B, a part of a message may be eliminated after encoding. This means that the code rate R is reduced gradually. Finally, the extending may be accomplished by adding parity bits after encoding. This enables the code rate R to be reduced gradually. The code rates may be changed by any one of the above-described manners. But, it is well comprehended that change of the code rates is not limited to this disclosure.

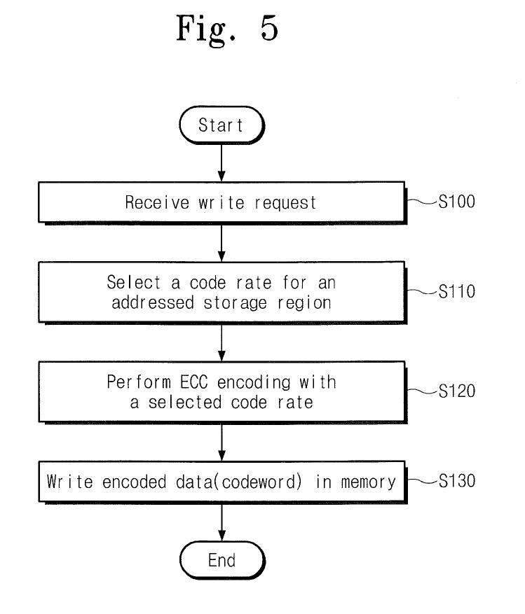

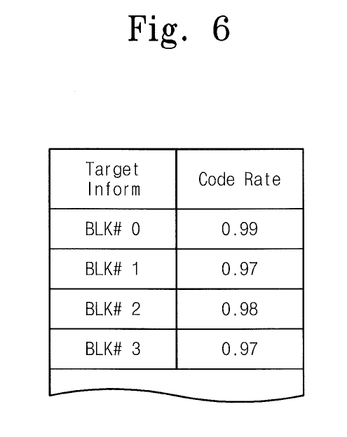

FIG. 5 is a flowchart showing a write operation of a data processing system according to an embodiment of the inventive concept, and FIG. 6 is a diagram showing code rates stored in a code rate storing part illustrated in FIG. 2. Below, a write operation of a data processing system will be more fully described with reference to the accompanying drawings.

In step S100, a write operation may be requested from an external device. If the write operation is requested, data being written may be temporarily stored in a buffer memory 2400. In step S110, a CSI deciding part 2620 may select a code rate, corresponding to a storage area being accessed, from a code rate storing part 2610 in response to address information of the write-requested storage area. For example, assume that a memory block BLK#0 is accessed. As illustrated in FIG. 6, a code rate of 0.99 may be selected by the CSI deciding part 2620. The selected code rate may be set to an ECC encoder 2510 through a code rate converting part 2630. If a code rate of a storage area being accessed is decided and the ECC encoder 2510 is set by the decided code rate, the procedure advances to step S120. In step S120, the ECC encoder 2510 may encode data transferred from the buffer memory 2400 according to the set code rate. In step S130, the encoded data, that is, a codeword may be written in the memory 1000.

In an exemplary embodiment, in the event that the ECC encoder 2510 has a concatenated encoding structure, although not illustrated in figures, a code rate of an outer encoder and a code rate of an inner encoder may be selected by the CSI deciding part 2620, respectively. The outer and inner encoders may operate according to the selected code rates, respectively. In this case, a codeword encoded by the outer encoder is encoded by the inner encoder, and a codeword encoded by the inner encoder is written in the memory 1000.

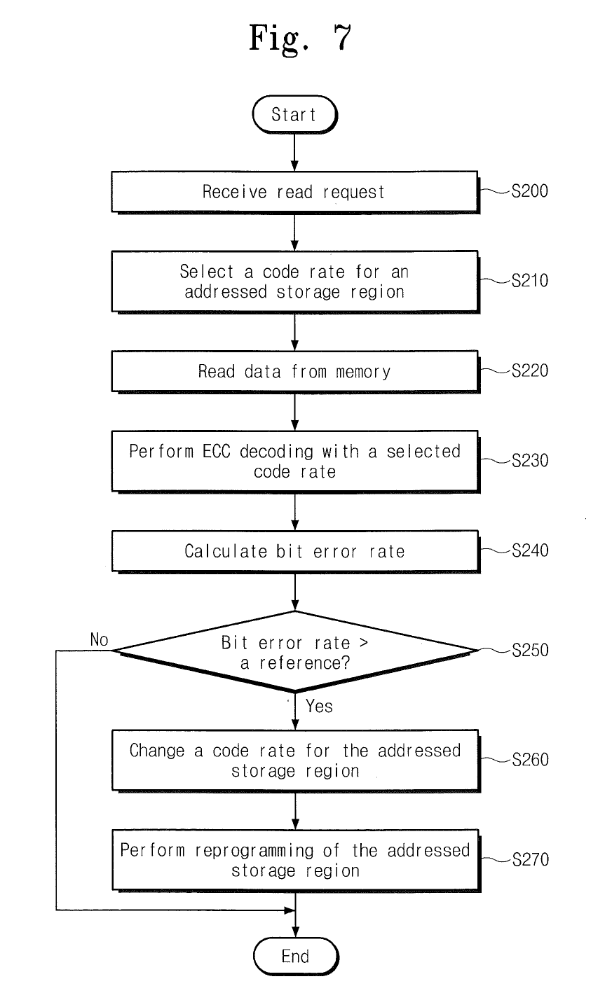

FIG. 7 is a flowchart showing a read operation of a data processing system according to an embodiment of the inventive concept. Below, a read operation of a data processing system will be more fully described with reference to the accompanying drawings.

In step S200, a read operation may be requested from an external device. If the read operation is requested, in step S210, a CSI deciding part 2620 may select a code rate, corresponding to a storage area being accessed, from a code rate storing part 2610 in response to address information of the write-requested storage area. For example, assume that a memory block BLK#3 is accessed. As illustrated in FIG. 6, a code rate of 0.97 may be selected by the CSI deciding part 2620. The selected code rate may be set to an ECC encoder 2510 through a code rate converting part 2630. If a code rate of a storage area being accessed is decided and the ECC encoder 2510 is set by the decided code rate, the procedure advances to step S220.

In step S220, data may be read out from the accessed storage area of the memory 1000. The read data RD may be sent to an ECC decoder 2520. The ECC decoder 2520 may decode the read data according to a code rate set by the code rate controlling block 2600. The decoded data may be temporarily stored in the buffer memory 2400 or provided to an external device. In step S240, the CSI deciding part 2620 may calculate a bit error rate (BER) based on the read data and the decoded data. In step S250, the CSI deciding part 2620 may judge whether the calculated BER is over a reference value. If the calculated BER is below the reference value, the read operation may be completed.

On the other hand, if the calculated BER is judged to be over the reference value, a code rate of the accessed storage area may be changed by the CSI deciding part 2620. For example, the CSI deciding part 2620 may change a code rate of the accessed storage area so as to be less than a previous code rate thereof. Once a code rate of the accessed storage area is changed, the procedure advances to step S270, in which a re-program operation for the accessed storage area is carried out. That is, data of the accessed storage area may be re-programmed at the same storage area or moved into another storage area based on the changed code rate. The re-program operation is not limited to this disclosure. Afterwards, the procedure may be terminated.

In an exemplary embodiment, the re-program operation may be made in a real time or in a background level according to a policy of the data processing system.

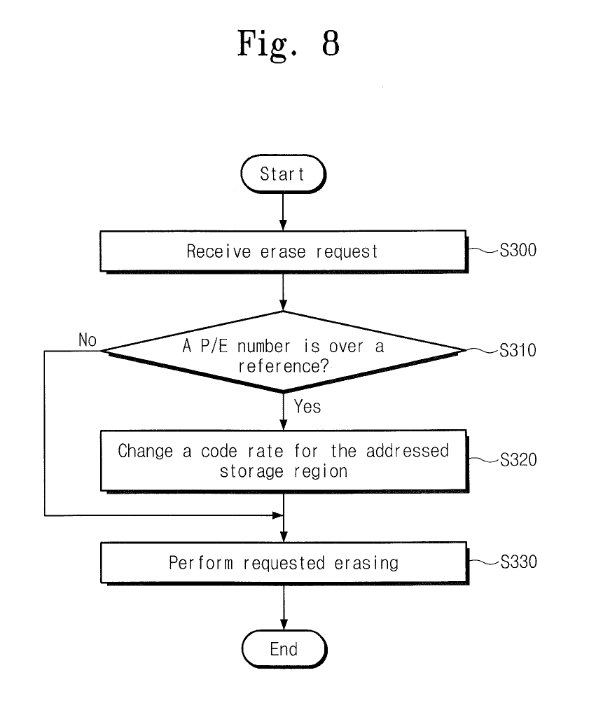

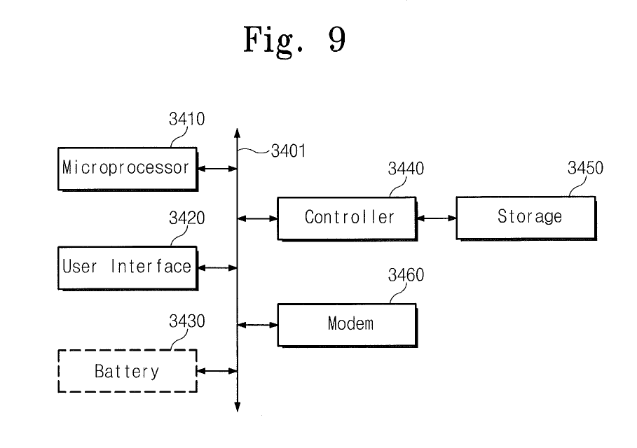

FIG. 8 is a flowchart showing an erase operation of a data processing system according to an embodiment of the inventive concept. Below, an erase operation of a data processing system will be more fully described with reference to the accompanying drawings.

In step S300, an erase operation may be requested from an external device. If an erase operation is requested, in step S310, a CSI deciding part 2620 may judge whether channel status information (for example, a program/erase number) of a storage area to be accessed exceeds a reference value. Herein, the CSI of the storage area being erased may be read from a buffer memory 2400 under the control of a processing unit 2300 or the CSI deciding part 2620. If the channel status information (for example, a program/erase number) of the storage area to be accessed is judged not to exceed the reference value, the procedure advances to step S330, in which the requested erase operation is carried out. On the other hand, if the channel status information (for example, a program/erase number) of the storage area to be accessed is judged to exceed the reference value, a code rate of the storage area being erased may be changed under the control of the CSI deciding part 2620. Afterwards, data to be stored/read in/from the erased storage area may be encoded/decoded according to the changed code rate. If the requested erase operation is completed, the procedure is completed.

As described above, a code rate of each storage area may be changed according to channel status information CSI such as wear-leveling information or a bit error rate (BER). But, a code rate of each storage area can be changed according to an access number of a storage area indicating whether data is long-term data or short-term data. Further, it is possible to form an ECC encoding and decoding block and/or a code rate controlling block in a memory 1000.

In an exemplary embodiment, operations of judging change of a code rate and setting a code rate may be made whenever a read/program operation is required. But, such operations can be carried out every given period. For example, it is possible to check a read number of a storage area or a memory and selectively perform such operations according to a checked result.

FIG. 9 is a block diagram showing a computing system including a memory and a controller illustrated in FIG. 1.

Referring to FIG. 9, a computing system is organized with including a processing unit 3410 such as a microprocessor or a central processing unit, a user interface 3420, a controller 3440, the storage media 3450, and a modem 3460 such as a baseband chipset, which are connected with a bus 3401. The controller 3440 and the storage media 3450 may be configured as like those shown FIG. 1 in substance. In the storage media 3450, N-bit data (N is a positive integer) to be processed by the processing unit 3410 are stored through the controller 3440. If the computing system shown in FIG. 9 is a mobile apparatus, it is further comprised of a battery 3430 for supplying power thereto. Although not shown in FIG. 9, the computing system may be further equipped with an application chipset, a camera image processor (e.g., CMOS image sensor; CIS), a mobile DRAM, etc. The controller 3440 and the storage media 3450 may form a solid state drive SSD or a memory card.

The storage media and/or the controller may be packed by various types of packages such as PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

The above-disclosed subject matter is to be considered illustrative, and not restrictive, and the appended claims are intended to cover all such modifications, enhancements, and other embodiments, which fall within the true spirit and scope. Thus, to the maximum extent allowed by law, the scope is to be determined by the broadest permissible interpretation of the following claims and their equivalents, and shall not be restricted or limited by the foregoing detailed description.

1. A processing system, comprising:
an error checking and correction (ECC) encoding circuit configured to selectively apply a plurality of unique ECC code rates to write data received by the data processing system during an operation to convert the write data into encoded data, in response to a code rate selection signal;
an integrated circuit memory having a plurality of storage regions therein that are configured to receive respective portions of the encoded data from said ECC encoding circuit; and
a code rate control circuit configured to generate the code rate selection signal having a value that specifies the corresponding ECC code rate to be applied to respective portions of the write data.

2. The data processing system of claim 1, wherein said code rate control circuit is further configured to set the value of the code rate selection signal so that each of the plurality of storage regions within said integrated circuit memory receive write data encoded with a unique ECC code rate.

3. The data processing system of claim 2, further comprising an ECC decoding circuit configured to decode first data read from a first storage region within said integrated circuit memory and determine a first bit error rate associated with the first data.

4. The data processing system of claim 3, wherein said ECC encoding circuit is further configured to reduce a code rate associated with write data being written to the first storage region in the event the first bit error rate determined by said ECC decoding circuit exceeds a first threshold.

5. The data processing system of claim 1, further comprising an ECC decoding circuit configured to decode first data read from a first storage region within said integrated circuit memory and determine a first bit error rate associated with the first data.

6. The data processing system of claim 5, wherein said ECC encoding circuit is further configured to reduce a code rate associated with write data being written to the first storage region in the event the first bit error rate determined by said ECC decoding circuit exceeds a first threshold.

7. A data processing system, comprising:
an integrated circuit memory having a plurality of storage regions therein;
an error checking and correction (ECC) encoding circuit responsive to a code rate selection signal, said ECC encoding circuit configured to encode first data at a first code rate determined by the code rate selection signal during an operation to write the first data into a first storage region within said integrated circuit memory;
an ECC decoding circuit configured to decode the first data read from the first storage region and determine a first bit error rate associated with the first data; and
a code rate control circuit configured to change a value of the code rate selection signal in the event the first bit error rate determined by said ECC decoding circuit exceeds a first threshold.

8. The data processing system of claim 7, wherein said code rate control circuit is further configured to set the value of the code rate selection signal so that each of the plurality of storage regions within said integrated circuit memory receive write data encoded with a unique code rate.

9. A data processing system comprising:
a memory having a plurality of storage areas;
an encoding and decoding block configured to decode data read out from an accessed storage area according to a set code rate; and
a code rate controlling block having code rates each corresponding to the plurality of storage areas and configured to set the encoding and decoding block with a code rate corresponding to a storage area being accessed among the plurality of storage areas.

10. The data processing system of claim 9, wherein the code rate controlling block is configured to change a code rate corresponding to the accessed storage area based on a bit error rate, the bit error rate being decided by data read out from the accessed storage area and data decoded by the encoding and decoding block.

11. The data processing system of claim 10, wherein if the bit error rate is more than a reference value, the code rate controlling block changes a code rate of the accessed storage area to be less than a previous code rate of the accessed storage area.

12. The data processing system of claim 11, wherein the code rates each corresponding to the plurality of storage areas are set to the largest code rate at an initial use point of time of the data processing system.

13. The data processing system of claim 11, wherein if a code rate of the accessed storage area is changed, data of the accessed storage area is re-programmed according to the changed code rate.

14. The data processing system of claim 9, wherein the encoding and decoding block is configured to perform encoding and decoding operations by a single code and two different codes.

15. The data processing system of claim 9, wherein at a write request, the code rate controlling block is configured to set the encoding and decoding block with a code rate corresponding to one being accessed among the plurality of storage areas, and the encoding and decoding block is configured to encode data to be stored according to the set code rate.

16. The data processing system of claim 9, wherein when an erase operation for the memory is requested, the code rate controlling block is configured to change a code rate a storage area being accessed, based on channel status information of the storage area being accessed.

17. The data processing system of claim 16, wherein when as the channel status information, a program/erase cycle of the storage area being accessed exceeds a reference value, the code rate controlling block changes a code rate of the storage area being accessed to be less than a previous code rate of the storage area being accessed.

18. The data processing system of claim 16, wherein the channel status information includes one selected from a group of a program/erase cycle, a used time, an error frequency after reading by decoding of an error control code at a read request, and a use for containing data.

19.-28. (canceled)
